(19) United States
(12) Patent Application Publication
(10) Pub. No.: US 2006/0128146 A1
(43) Pub. Date: Jun. 15, 2006

(54) METHOD OF FORMING BARRIER LAYER AND METHOD OF FABRICATING INTERCONNECT

(76) Inventors: Chia-Lin Hsu, Tainan City (TW); Shu-Jen Chen, Hsinchu City (TW); Jih-Cheng Yeh, Tainan City (TW); Chih-Chiang Wu, Taichung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,435

(22) Filed: Oct. 19, 2005

Related U.S. Application Data
(60) Provisional application No. 60/634,912, filed on Dec. 10, 2004.

(51) Int. Cl. H01L 21/44

(52) U.S. Cl. 438/656; 438/679; 438/687; 438/686

(57) ABSTRACT

A method of fabricating a barrier layer is described. A material layer having an opening formed therein is provided. Then, the material layer is disposed inside a physical vapor deposition chamber and a first deposition process is performed to form a first barrier layer on the surface of the opening. The first deposition process includes turning on a plasma source and turning off the plasma source. The turning on of the plasma source and the turning off of the plasma source are separated from each other by an interval less than 2 seconds. Thereafter, the first deposition process is repeated several times to form a second barrier layer comprising a plurality of first barrier layers.

### CROSS-REFERENCE TO RELATED APPLICATION

This application claims the priority benefit of U.S.A. provisional application Ser. No. 60/634,912, filed Dec. 10, 2004, all disclosures are incorporated therewith.

### BACKGROUND OF THE INVENTION

1. Field of the Invention

The present invention relates to a semiconductor manufacturing process. More particularly, the present invention relates to a method of forming a barrier layer and a method of fabricating interconnects.

2. Description of the Related Art

With the rapid development of integrated circuit manufacturing industry, the size of devices continue to shrink and the level of integration continues to increase. Hence, there is insufficient area on the surface of the wafer to accommodate all required metallic interconnects. To meet the increasing demand for metallic interconnect, designs having two or more metallic layers have been developed. In particular, some functionally complex electronic products such as microprocessors need to have a total of up to four to five metallic layers before all the devices are interconnected.

Due to the high electro-migration resistance and low electrical resistance of copper, the time delay in signal transmission of device can be reduced, and copper has been widely adopted in wiring structures. In fact, copper has gradually replaced aluminum as the most popular material for forming metallic interconnects.

In general, the conventional interconnect process includes forming a dielectric layer over a substrate with devices formed thereon. Then, an opening is formed in the dielectric layer. After that, a physical vapor deposition (PVD) process is performed to form a barrier layer on the surface of the opening. Thereafter, a copper layer is formed over the substrate to fill up the opening. Then, the copper layer is planarized to remove excess metallic material on the surface of the dielectric layer. However, the PVD process has poor gap-filling capacity and the thickness of the deposited barrier layer is non-uniform so that the barrier layer on the upper end of the opening is thickened. As a result, there are some difficulties in filling the opening with copper. Ultimately, leakage current in the device occurs quite frequently.

To enhance the gap-filling capacity of copper, overall thickness of the barrier layer must be reduced to ensure the upper end of the opening has sufficient space left over for the entrance of copper as the line width gradually reduced. Therefore, an atomic layer deposition (ALD) method can be used in the process of forming the barrier layer. However, the barrier layer produced by the ALD method often has insufficient adhesion and too high electrical resistance.

### SUMMARY OF THE INVENTION

Accordingly, at least one objective of the present invention is to provide a method of forming a barrier layer capable of reducing the thickness, lowering the electrical resistance and increasing the adhesion of the barrier layer.

At least one objective of the present invention is to provide a method of fabricating interconnects capable of reducing the thickness and the resistance of a barrier layer and increasing the adhesion of the barrier layer.

To achieve these and other advantages and in accordance with the purpose of the invention, as embodied and broadly described herein, the invention provides a method of forming a barrier layer. First, a material layer having an opening formed therein is provided. Then, the material layer is disposed inside a physical vapor deposition chamber and a first deposition process is performed to form a first barrier layer on the surface of the opening. The first deposition process includes turning on a plasma source and turning off the plasma source. The turning on of the plasma source and the turning off of the plasma source are separated from each other by an interval less than 2 seconds. Thereafter, the first deposition process is repeated several times to form a second barrier layer comprising a plurality of first barrier layers.

According to the method of forming a barrier layer in the embodiment of the present invention, the first barrier layer is fabricated using tantalum (Ta), tantalum nitride (TaN), titanium (Ti), titanium nitride (TiN) or ruthenium (Ru), for example.

According to the method of forming a barrier layer in the embodiment of the present invention, the first barrier layer has a thickness small than 10 Å, for example.

According to the method of forming a barrier layer in the embodiment of the present invention, after forming the second barrier layer, may further includes performing a second deposition process in the PVD chamber to form a third barrier layer on the second barrier layer.

According to the method of forming a barrier layer in the embodiment of the present invention, the third barrier layer is fabricated using tantalum, tantalum nitride, titanium, titanium nitride or ruthenium, for example.

The present invention also provides a method of fabricating interconnects. First, a substrate having a dielectric layer formed thereon is provided. Furthermore, the dielectric layer has a plurality of openings. Then, the substrate is placed inside a physical vapor deposition (PVD) reaction chamber and a first deposition process is performed to form a first barrier layer on the surface of the opening. The first deposition process includes turning on a plasma source and turning off the plasma source. The turning on of the plasma source and the turning off of the plasma source are separated from each other by an interval less than 2 seconds. Thereafter, the first deposition process is repeated several times to form a second barrier layer comprising a plurality of first barrier layers. After that, a metallic layer is formed to fill the opening.

According to the method of forming interconnects in the embodiment of the present invention, the first barrier layer is fabricated using tantalum, tantalum nitride, titanium, titanium nitride or ruthenium, for example.

According to the method of forming interconnects in the embodiment of the present invention, the first barrier layer has a thickness small than 10 Å, for example.

According to the method of forming interconnects in the embodiment of the present invention, after forming the second barrier layer, may further includes performing a second deposition process in the PVD chamber to form a third barrier layer on the second barrier layer.

According to the method of forming interconnects in the embodiment of the present invention, the third barrier layer is fabricated using tantalum, tantalum nitride, titanium, titanium nitride or ruthenium, for example.

According to the method of forming interconnects in the embodiment of the present invention, the metallic layer is fabricated using copper, for example.

According to the method of forming interconnects in the embodiment of the present invention, the dielectric layer is fabricated using a low dielectric constant (K) material, for example.

The present invention utilizes a multiple of short-duration physical vapor deposition processes to form the barrier layer with each deposition process producing a thin barrier layer. Therefore, by repeating the same short-duration PVD processes, overall thickness of the barrier layer can be minimized. In the meantime, a barrier layer fabricated through a multiple of short-duration PVD processes has lower resistance, a greater adhesive strength and a higher degree of hardness than a conventional barrier layer.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow diagram showing the steps for forming a barrier layer according to one embodiment of the present invention.

FIGS. 2A through 2D are schematic cross-sectional views showing the steps for producing interconnects according to one embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

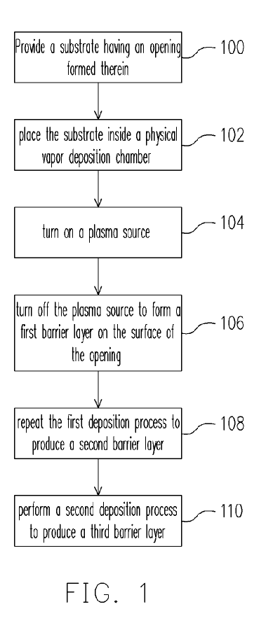

FIG. 1 is a flow diagram showing the steps for forming a barrier layer according to one embodiment of the present invention. As shown in FIG. 1, in step 100, a material layer having an opening formed therein is provided. The material layer is a dielectric layer, for example. Conductive material can be deposited into the opening in the material layer in a subsequent process to form an interconnect. The opening can be a damascene opening, a contact opening, a via opening or a trench. Then, the material layer is placed inside a physical vapor deposition (PVD) reaction chamber (in step 102). Thereafter, a plasma source is turned on (in step 104) so that plasma is created to initiate the PVD deposition. Then, in step 106, the plasma source is turned off to stop the passage of plasma into the reaction chamber so that a first barrier layer is formed on the surface of the opening. The first barrier layer is fabricated using tantalum, tantalum nitride, titanium, titanium nitride or ruthenium, for example. It should be noted that the steps 104 and 106 in the present embodiment are usually grouped together and considered as a first deposition process. In addition, the time interval separating the first step 104 and the second step 106 is typically short, for example, within 2 seconds.

Because the duration of the physical vapor deposition (PVD) is very short, the first barrier layer on the surface of the opening is quite thin, for example, smaller than 10 Å. Thereafter, the first deposition process is repeated several times (in step 108) to form a second barrier layer comprising a plurality of thin first barrier layers. Furthermore, the time interval between turning the plasma source on and turning the plasma source off is similarly less than 2 seconds. Consequently, the aforesaid method of forming the second barrier layer not only can reduce the overall thickness of the second barrier layer to a minimum, but can also lower the resistance and increase the adhesive strength of the second barrier layer. In another embodiment of the present invention, after the second barrier layer is formed, an optional step 110 of performing a second physical vapor deposition process may be further included to form a third barrier layer on the second barrier layer. The third barrier layer is formed using a conventional physical vapor deposition method, and the third barrier layer has a thickness of about 60 Å to 150 Å, for example.

It should be noted that a multiple of short-duration physical vapor deposition processes can be used to form a plurality of ultra-thin first barrier layers whose total thickness accumulates to about 100 Å. Alternatively, in another embodiment, a multiple of short-duration physical vapor deposition processes can be carried out to produce a plurality of thin first barrier layers so that a second barrier layer having a predetermined thickness is formed. The predetermined thickness is about 40 Å, for example. Thereafter, inside the same PVD reaction chamber, a second deposition process is carried out using a conventional physical vapor deposition method. The plasma source is turned on to form a thicker third barrier layer on the second barrier layer. The third barrier layer is fabricated using tantalum, tantalum nitride, titanium, titanium nitride or ruthenium, for example. Furthermore, the third barrier layer has a thickness of about 60 Å, for example. Hence, a barrier layer having a total thickness of about 100 Å is produced.

In addition, the aforesaid method of forming a barrier layer in the present invention can be applied to fabricate interconnects so that the overall thickness of the barrier layer is reduced to a minimum so that copper can have a better gap-filling capacity.

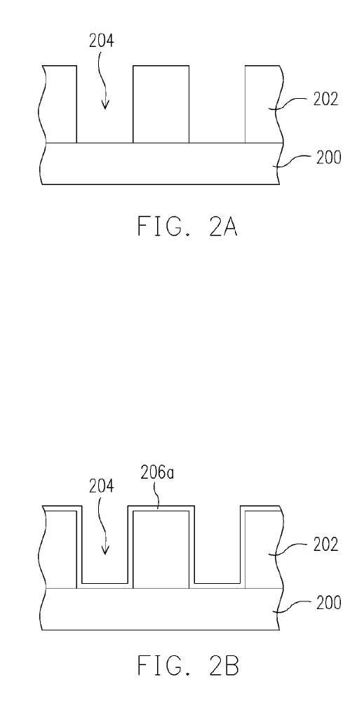

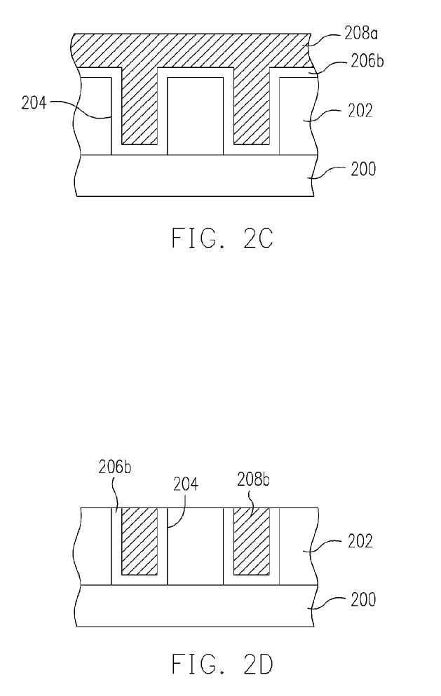

FIGS. 2A through 2D are schematic cross-sectional views showing the steps for producing interconnects according to one embodiment of the present invention. As shown in FIG. 2A, a substrate 200 such as a silicon substrate is provided. The substrate 200 has semiconductor devices (not shown) such as metal-oxide-semiconductor (MOS) transistor or conductive lines and a dielectric layer 202 with a plurality of openings 204 already formed thereon. The dielectric layer 202 is fabricated using a low dielectric constant (K) material, for example. Conductive material is deposited into the openings 204 in a subsequent process to produce interconnects. The openings 204 can be a damascene opening, a contact opening, a via opening or a trench, for example.

As shown in FIG. 2B, a first deposition process is performed to form a very thin barrier layer 206a on the surface of the opening 204. The thin barrier layer 206a is fabricated using tantalum, tantalum nitride, titanium, titanium nitride or ruthenium, for example. To perform the first deposition process, the substrate 200 is placed inside a physical vapor deposition (PVD) reaction chamber. Then, a plasma source is turned on to produce plasma for the PVD process. A moment later, the plasma source is turned off to stop the passage of plasma and form the barrier layer 206a with a thickness smaller than 10 Å, for example. Furthermore, the time interval between turning the plasma source on and turning it off is less than 2 seconds.

As shown in FIG. 2C, the plasma source is turned on and off several times inside the same PVD reaction chamber to form a barrier layer 206b comprising a plurality of the barrier layers 206a. Hence, not only the overall thickness of the barrier layer 206b is reduced to a minimal, but also the resistance is reduced and the adhesive strength of the barrier layer 206b is also improved.

It should be noted that the number of times turning the plasma source on and off depends on the required thickness of the barrier layer. In general, the barrier layer has a thickness of about 100 Å so that the number of on/off switching of the plasma source is a few tens, for example.

Thereafter, as shown in FIG. 2C, a metal layer 208a is formed on the substrate 200 to fill the opening 204. The metal layer 208a is fabricated using copper, for example. Then, as shown in FIG. 2D, a planarization process including, for example, a chemical-mechanical polishing process is carried out to remove some of the metal layer 208a and barrier layer 206b on the surface of the dielectric layer 202, thereby forming a plug 208b.

Similarly, in another embodiment, the short-duration PVD process of the present invention can be applied a multiple of times to produce a certain part of the barrier layer 206b before using the conventional PVD process to produce the remaining part of the barrier layer 206b. Since the short-duration PVD process is identical to the aforesaid embodiment, a detailed description is not repeated.

In summary, the barrier layer in the present invention is formed by performing a multiple of short-duration PVD processes instead of the conventional PVD process or atomic layer deposition process. Thus, a very thin barrier layer is formed in each PVD process so that the overall thickness of the barrier layer can be reduced to the minimal. As a result, the gap-filling capacity of the copper is improved. In addition, the barrier layer obtained from a multiple of short-duration PVD processes has a lower resistance and a higher adhesive strength as well. Moreover, the barrier layer of the present invention is harder than the ones formed by other conventional methods.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a barrier layer, comprising the steps of:
providing a material layer, wherein the material layer has an opening formed therein;
placing the material layer inside a physical vapor deposition chamber and performing a first deposition process to form a first barrier layer on the surface of the opening, wherein the first deposition process comprises:
turning on a plasma source; and
turning off the plasma source, wherein the interval between turning on the plasma source and turning off the plasma source is less than 2 seconds; and
repeating the first deposition process several times to form a second barrier layer, wherein the second barrier layer comprises a stack of first barrier layers.

2. The method of forming the barrier layer of claim 1, wherein the material constituting the first barrier layer comprises tantalum (Ta), tantalum nitride (TaN), titanium (Ti), titanium nitride (TiN) or ruthenium (Ru).

3. The method of forming the barrier layer of claim 1, wherein the first barrier layer has a thickness smaller than 10 Å.

4. The method of forming the barrier layer of claim 1, wherein after forming the second barrier layer, further comprises performing a second deposition process inside the PVD chamber to form a third barrier layer on the second barrier layer.

5. The method of forming the barrier layer of claim 4, wherein the material constituting the third barrier layer comprises tantalum, tantalum nitride, titanium, titanium nitride or ruthenium.

6. A method of fabricating interconnects, comprising the steps of:
providing a substrate having a dielectric layer formed thereon, wherein the dielectric layer has a plurality of openings formed therein;
placing the substrate inside a physical vapor deposition chamber and performing a first deposition process to form a first barrier layer on the surface of the openings, wherein the first deposition process comprises:
turning on a plasma source; and
turning off the plasma source, wherein the interval between turning the plasma source on and the plasma source off is less than 2 seconds;
repeating the first deposition process several times to form a second barrier layer, wherein the second barrier layer comprises a stack of first barrier layers; and
forming a metal layer that fills the openings.

7. The method of fabricating interconnects of claim 6, wherein the material constituting the first barrier layer comprises tantalum, tantalum nitride, titanium, titanium nitride or ruthenium.

8. The method of fabricating interconnects of claim 6, wherein the first barrier layer has a thickness smaller than 10 Å.

9. The method of fabricating interconnects of claim 6, wherein after forming the second barrier layer, further comprises performing a second deposition process inside the PVD chamber to form a third barrier layer on the second barrier layer.

10. The method of fabricating interconnects of claim 9, wherein the material constituting the third barrier layer comprises tantalum, tantalum nitride, titanium, titanium nitride or ruthenium.

11. The method of fabricating interconnects of claim 6, wherein the material constituting the metal layer comprises copper.

12. The method of fabricating interconnects of claim 6, wherein the material constituting the dielectric layer comprises a low dielectric constant (K) material.
